(19) United States
(12) Patent Application Publication
(10) Pub. No.: US 2016/0252721 A1
(43) Pub. Date: Sep. 1, 2016

(54) OPTICAL ARRANGEMENT, ENDOSCOPE AND CORRESPONDING PRODUCTION METHOD

(71) Applicant: Scholly Fiberoptic GmbH, Denzlingen (DE)

(72) Inventors: Matthias Kuhn, Freiburg i. Br. (DE); Massimo Kubon, Emmendingen (DE)

(73) Assignee: Scholly Fiberoptic GmbH, Denzlingen (DE)

(21) Appl. No.: 15/018,032

(22) Filed: Feb. 8, 2016

(30) Foreign Application Priority Data
Feb. 28, 2015 (DE) 102015002536.8

(51) Int. Cl. G02B 23/24; H01L 27/146; G02B 13/00

(52) U.S. Cl. CPC G02B 23/2415; G02B 23/2446; G02B 13/0085; H01L 27/14625; H01L 27/14632; H01L 27/14685; H01L 27/14687

(57) ABSTRACT

In the case of an optical arrangement (1) including functional units (9, 10, 11, 12) which are arranged in a stack arrangement (8) and define a first optical channel (2) and a second optical channel (3), it is provided here to form a common image sensor chip for both optical channels (2, 3) in a functional unit (12) or to separate the optical channels (2, 3) from one another by the functional units (9, 10, 11) without any gaps.

### INCORPORATION BY REFERENCE

The following documents are incorporated herein by reference as if fully set forth: German Patent Application No. 102015002536.8, filed Feb. 28, 2015.

### BACKGROUND

The invention relates to an optical arrangement, comprising a first optical channel and a second optical channel and optical elements arranged in a stack arrangement in the first optical channel and in the second optical channel, wherein respectively corresponding optical elements of the first optical channel and of the second optical channel are connected to one another as a functional unit.

Such arrangements are known from stereoscopic arrangements, for example, and are used in endoscopes, for example, in order to enable a spatial recording of a field of view at a distal end of the endoscope.

The invention furthermore relates to a method for producing an optical arrangement, wherein the optical arrangement has a stack arrangement of functional units respectively defining a first optical channel and a second optical channel. The optical arrangement can be formed here in the manner as described above.

The production of an optical arrangement is performed in a multiplicity of more or less complex individual steps which hitherto have been necessary inter alia for incorporating the optical elements and for aligning the optical elements on one another.

### SUMMARY

The invention is based on the object of simplifying the production of an optical arrangement.

In order to achieve the stated object, the one or more features of invention are provided. In particular, therefore, according to the invention, in the case of an optical arrangement of the type described in the introduction, it is provided according to the invention that a common image sensor chip is designed for detecting the first optical channel and the second optical channel. What is advantageous here is that a separate alignment of an image sensor chip for the second optical channel relative to an image sensor chip for the first optical channel can be dispensed with. What is furthermore advantageous is that respective recording areas on the image sensor chip for the second optical channel and for the first optical channel can be arranged closer together. As a result, unused spaces or regions between the optical channels can be reduced or even completely avoided. Consequently, a small external size is achievable, which is particularly expedient in the case of a miniaturized image recording device for example in an endoscope. The image recording chip is preferably arranged in a distal end of said endoscope. Consequently, optical image guides can be dispensed with to the greatest possible extent or completely. In addition, the production costs and a circuitry outlay can be reduced by the use of a common image recording chip.

Alternatively or additionally, in order to achieve the stated object, additional features of the invention are provided. In particular, therefore, according to the invention, in the case of an optical arrangement of the type described in the introduction, it is additionally or alternatively provided that the functional units in the stack arrangement separate the first optical channel from the second optical channel without any gaps. What is advantageous here is that crosstalk between the optical channels as a result of stray light, for example, can be avoided in a simple manner, such that additional compartmentalizations can be dispensed with. A reduction of parts is thus achievable, which simplifies production. In addition, with the invention the optical channels can be arranged closer to one another or at a smaller distance from one another, as a result of which a smaller external size of the optical arrangement is achievable. This is particularly expedient for a miniaturization.

In one configuration of the invention, it can be provided that the functional units are formed in a plate-shaped fashion. Consequently, the functional units are mountable and in particular stackable in a simple manner. It is particularly expedient if the functional units are cut in each case from a wafer. What is advantageous here is that structuring processes and shaping processes from wafer technology can be used for cost-effective production. In this case, a wafer can be characterized as a plate-shaped object which is produced integrally from a crystalline material, for example from silicon or a silicon compound, polycrystalline material or amorphous material, for example from a polymer.

In one configuration of the invention, it can be provided that respectively adjacent functional units are placed onto one another directly. A situation in which they lie one on top of another without any gaps is thus achievable. Intermediate parts between the functional units can be dispensed with. By virtue of the functional units lying one on top of another directly and without any gaps, a defined alignment of the functional units with respect to one another is achievable in a simple manner.

In one configuration of the invention, it can be provided that the first optical channel and the second optical channel are formed in each case by mutually aligned sections in the functional units. What is advantageous here is that the optical channels can be formed in a manner closed off toward the outside sideways and continuously in a simple manner. Stray light influences can thus be reduced. The sections here can be in each case such that they accommodate and/or form an optical element, for example accommodate and/or form at least one lens, diaphragm, filter, diffraction grating, protective or covering plate. Consequently, it is possible to provide different functional units for the configuration of a desired functionality of the optical channels. It is expedient if in each functional unit the section of the first optical channel is arranged at a distance from the section of the second optical channel. Consequently, the respective functional unit forms an isolation means between the optical channels in order to avoid mutual interference. Preferably, a distance between the optical channels in each functional unit is filled with a preferably light-nontransmissive material.

In one configuration of the invention, it can be provided that the functional units in each case have a frame composed of a wafer. It is thus possible to provide a stable receptacle or mount for optical elements. The wafer can be a polymer wafer. It is particularly expedient if the wafer is produced from PC (polycarbonate) and/or PMMA (polymethyl methacrylate, Plexiglas) and/or COC (cycloolefin copolymer). Alternatively or additionally, it can be provided that the functional units in each case have a frame composed of an optically nontransmissive material. Stray light influences can thus be suppressed in a simple manner.

In one configuration of the invention, it can be provided that at least one of the functional units comprises an optical isolation element between the first optical channel and the second optical channel. What is advantageous here is that crosstalk between the optical channels can be reduced or even avoided, even if the functional unit is otherwise produced from a transparent or light-transmissive material. Reliable isolation of the optical channels from one another is thus possible in a simple manner even if the functional unit comprises an optical element, for example a lens, which is formed integrally on a frame. Preferably, the isolation elements of the functional units are arranged in a manner coordinated with one another.

In one configuration of the invention, it can be provided that the first optical channel and/or the second optical channel are/is closed off in each case transversely with respect to a course direction on all sides toward the outside and/or relative to one another. What is advantageous here is that crosstalk of stray light between the optical channels and/or an interference influence as a result of stray light from outside and/or from the respective other channel can be avoided.

In one configuration of the invention, it can be provided that the functional units are produced by thermoforming and/or reshaping or primary forming, in particular by an injection molding, pressing, stamping and/or embossing method, for example precision blank pressing. Consequently, the functional units with the optical elements can be formed cost-effectively and structurally flexibly. Mounting of the molded, pressed and/or embossed functional units can be simplified because assembly of the individual functional units can be dispensed with.

In one configuration of the invention, it can be provided that the optical arrangement is embodied as a stereoscopic optical arrangement. This can be achieved, for example, by virtue of the fact that the first optical channel is embodied as a right optical channel and/or the second optical channel is embodied as a left optical channel. What is advantageous here is that three-dimensional spatial information can be detected and provided by the optical arrangement.

Alternatively or additionally, it can be provided that the first optical channel and the second optical channel are designed for mutually differing wavelength ranges. What is advantageous here is that different items of information can be detected simultaneously. By way of example, it is thus possible to detect fluorescence alongside visible phenomena. Alternatively or additionally, in this way it is possible to detect temperature information or heat information alongside the visible information.

Alternatively or additionally, it can be provided that the first optical channel and the second optical channel define different aperture angles. It is advantageous here that wide-angle recordings and zoom recordings can be recorded simultaneously. Alternatively or additionally, it can be provided that the first optical channel and the second optical channel are designed for different recording directions. What is advantageous here is that the detectable overall field of view or the detectable overall aperture angle can be increased. Alternatively or additionally, it can be provided that the first optical channel and the second optical channel define different diaphragm apertures. What is advantageous here is that different recordings, for example with different depths of field, can be obtained simultaneously. Alternatively or additionally, it can be provided that the first optical channel part and the second optical channel define different focal lengths. What is advantageous here is that different image excerpts and/or different items of depth information can be obtained.

One particularly advantageous application of the invention is given by an endoscope comprising an optical arrangement according to the invention, in particular as described above and/or as claimed in any of the claims directed to an optical arrangement. In endoscopes, the miniaturization opened up by the invention can be used particularly advantageously with expedient production costs.

In order to achieve the stated object, the features of the independent method claim are provided according to the invention. In particular, therefore, according to the invention, in order to achieve the object, in the case of a method of the type described in the introduction, it is proposed that the functional units are formed on a respective wafer, that the wafers with the functional units are placed onto one another in order to form the stack arrangement, and that the wafers placed onto one another are cut apart in order to singulate the optical arrangement. In this case, the stereoscopic arrangement can be embodied according to the invention, in particular as described above and/or as claimed in any of the claims directed to a stereoscopic optical arrangement. Consequently, an alignment of the functional units with respect to one another can already be effected on the wafers having a macroscopic extent. As a result, it is possible to simplify handling during production.

In one configuration of the invention, it can be provided that the respective functional unit is formed multiply on each wafer. What is advantageous here is that mass production can be carried out.

In one configuration of the invention, it can be provided that the wafers in the position placed onto one another are connected to one another. What is advantageous here is that an established alignment of the functional units with respect to one another can be permanently maintained. Preferably, the connection is formed cohesively, for example by adhesive bonding, bonding and/or welding. Compact, robust optical arrangements can thus be formed.

In one configuration of the invention, it can be provided that the functional units are produced by an injection molding, pressing, stamping and/or embossing method. Cost-effective production methods can thus be used.

### BRIEF DESCRIPTION OF THE DRAWINGS

The invention will now be described in greater detail on the basis of exemplary embodiments, but is not restricted to these exemplary embodiments. Further exemplary embodiments arise through combination of the features of individual or a plurality of claims among one another and/or with individual or a plurality of features of the exemplary embodiments.

In the Figures, in a greatly simplified illustration for the purposes of elucidating the invention:

FIG. 1 shows an arrangement of individual, separate wafers before the production method according to the invention is carried out,

FIG. 2 shows the wafers in accordance with FIG. 1 in a position in which the wafers touch and thus lie one on top of another directly and without any gaps,

FIG. 3 shows functional units of an optical arrangement according to the invention in an exploded illustration,

FIG. 4 shows the functional units in accordance with FIG. 3 in an interconnected position after the conclusion of the method according to the invention for forming a stereoscopic optical arrangement according to the invention,

FIG. 5 shows functional units of a further stereoscopic optical arrangement according to the invention in an exploded illustration,

FIG. 6 shows the functional units in accordance with FIG. 5 in a position in which the functional units lie one on top of another directly and without any gaps in order to form a stereoscopic optical arrangement according to the invention,

FIG. 7 shows a further optical arrangement according to the invention in a three-dimensional oblique illustration,

FIG. 8 shows a further optical arrangement according to the invention comprising more than two optical channels,

FIG. 9 shows further optical arrangements according to the invention comprising different arrangements and numbers of optical channels in a view of a distal end in each case from the front, and

FIG. 10 shows a further optical arrangement according to the invention having differently aligned recording directions in a three-dimensional oblique illustration.

### DETAILED DESCRIPTION OF THE PREFERRED EMBODIMENTS

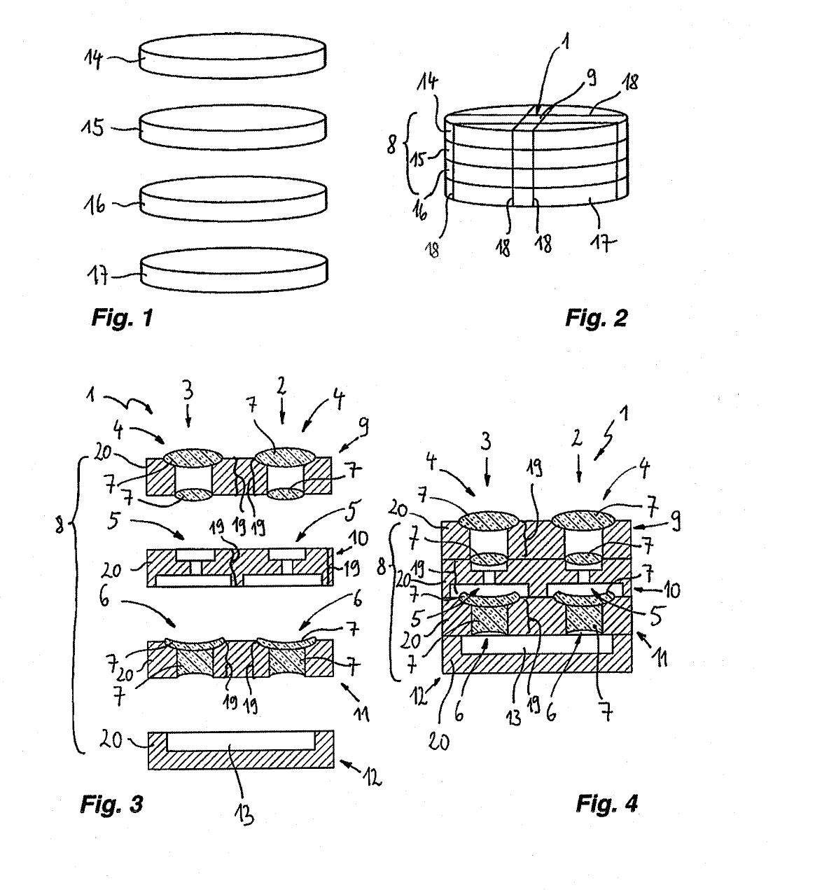

FIGS. 1 to 4 show, in a greatly simplified illustration, a method according to the invention for producing an optical arrangement, which is designated as a whole by 1 and which is shown here as a stereoscopic optical arrangement.

In this case, FIG. 4 shows the finished assembled optical arrangement 1 in a sectional illustration, while FIG. 3 illustrates an exploded illustration of said optical arrangement 1 for illustrating the invention.

The optical arrangement 1 accordingly comprises a first optical channel 2, which is embodied as a right optical channel, and a second optical channel 3, which is embodied as a left optical channel, which are arranged in a manner offset laterally with respect to one another for the purpose of stereoscopic vision in a manner known per se.

In this case, the optical channels 2, 3 are defined by optical elements 4, 5, 6.

The illustration in accordance with FIG. 3 and FIG. 4 here shows the optical elements 4, 5, 6 in each case in pairs, wherein one optical element 4, 5, 6 of a pair is assigned to the first optical channel 2 and another optical element 4, 5, 6 of the same pair is assigned to the second optical channel 3.

In the drawings, the optical elements 4 and 6 are illustrated as lens arrangements of different lenses 7. Depending on the requirements made of the optical channel 2, 3, other arrangements of lenses 7 and/or more or fewer optical elements are also provided in further exemplary embodiments.

FIGS. 3 and 4 furthermore show the optical element 5 by way of example as a diaphragm. Here, too, in further exemplary embodiments of the invention, other diaphragm shapes or other optical elements can be provided in the position shown or at other positions. By way of example, an optical element which realizes a diaphragm can be arranged at an entrance of each of the optical channels 2, 3 in addition or as an alternative to the optical element 5.

The optical elements 4, 5, 6 of each optical channel 2, 3 are arranged one above another in a stack arrangement 8.

The optical elements 4, 5, 6 of the first optical channel 2 and of the second optical channel 3 which respectively correspond to one another are formed in each case in pairs on a common functional unit 9, 10, 11 and are thus connected to one another.

These functional units 9, 10, 11 are placed one on top of another in the stack arrangement 8.

The stack arrangement 8 is terminated by a functional unit 12 at one end. An image sensor chip 13 used jointly by the first optical channel 2 and the second optical channel 3 is arranged in the functional unit 12. In this case, the functional unit 12 can be produced from a silicon wafer with integrated image sensor chip 13.

It can be seen in FIG. 4 that the functional units 9, 10, 11, 12 are placed one directly on top of another in the stack arrangement 8, such that no laterally continuous gaps connecting the optical channels 2, 3 occur between the functional units 9, 10, 11, 12. A distance between the optical channels 2, 3 is thus filled by a material of the respective functional unit 9, 10, 11.

As a result of this, the first optical channel 2 is separated from the second optical channel 3 by the functional units 9, 10, 11.

In the production method according to the invention, the functional units 9, 10, 11, 12 are produced from a respective wafer 14, 15, 16, 17 provided for said functional unit 9, 10, 11, 12.

For this purpose, the functional unit 9 is formed on the wafer 14, the functional unit 10 on the wafer 15, the functional unit 11 on the wafer 16 and the functional unit 12 on the wafer 17.

For this purpose, by way of example, the lenses 7 of the optical elements 4, 6 are inserted into corresponding receptacles on the functional unit 9 and 11, respectively, in the wafer 14 and 16, respectively. The optical element 5 can be formed for example by an embossing or stamping step in the functional unit 10 on the wafer 15. The image sensor chip 13 can be inserted or molded into the functional unit 12 on the wafer 17. These examples serve to illustrate the invention and can be combined or varied differently as required.

The wafers 14, 15, 16, 17 in accordance with FIG. 1 here are significantly larger than the functional units 9, 10, 11, 12 and allow the multiple formation of the respective functional units 9, 10, 11, 12 on the wafer 14, 15, 16, 17. Each wafer, 14, 15, 16, 17 therefore contains a plurality of identical functional units 9, 10, 11, 12 alongside one another in the production step in accordance with FIG. 1.

The plate-shaped wafers 14, 15, 16, 17 are then placed one directly on top of another in order to form the stack arrangement 8, such that no gaps remain between the wafers 14, 15, 16, 17. Mutually adjacent wafers 14, 15, 16, 17 thus touch areally. In this case, the wafers 14, 15, 16, 17 are aligned with one another such that the functional units 9, 10, 11, 12 are brought to congruence with one another. These functional units 9, 10, 11, 12 thus form a respective optical arrangement.

Cuts 18 are then introduced into the stack arrangement 8 of wafers 14, 15, 16, 17 in a customary manner, by which cuts the wafers 14, 15, 16, 17 are cut up in order to singulate the optical arrangements 1.

In this way, many optical arrangements 1 in accordance with FIG. 4 arise from a stack arrangement 8 of wafers 14, 15, 16, 17.

It can be seen in FIG. 4 that a respective section 19 is formed in the functional units 9, 10, 11, said section accommodating the respective optical elements 4, 5, 6. Said sections 19 are enclosed in pairs by a respective frame 20 of the functional unit 9, 10, 11, 12.

FIG. 4 depicts the sections 19 by way of example only for the second optical channel 3. It is evident that corresponding sections which accommodate the respective optical elements 4, 5, 6 are formed for the first optical channel 2.

The sections 19 of the functional units 9, 10, 11 of an optical channel 2, 3 are aligned with one another, thus giving rise to the respective optical channel 2, 3.

In this case, the sections 19 of the second optical channel 3 are arranged in a manner spaced apart from the corresponding sections 19 of the first optical channel 2 on the respective functional unit 9, 10, 11.

The contacting of the adjacent functional units 9, 10, 11 without any gaps achieves the effect that the optical channels 2, 3 in the sections 19 in the course direction of the respective optical channel 2, 3 are closed off toward the outside laterally on all sides. In particular, therefore, the optical channels 2, 3 are closed off relative to one another and separated from one another.

In the exemplary embodiment from FIGS. 1 to 4, the wafers 14, 15, 16, 17 are embodied as polymer wafers, for example comprised of polycarbonate or PMMA or COC. The material is optically nontransmissive in this case, such that the optical channels 2, 3 are isolated from one another and no stray light can cross from one optical channel 2, 3 into the other optical channel 2, 3.

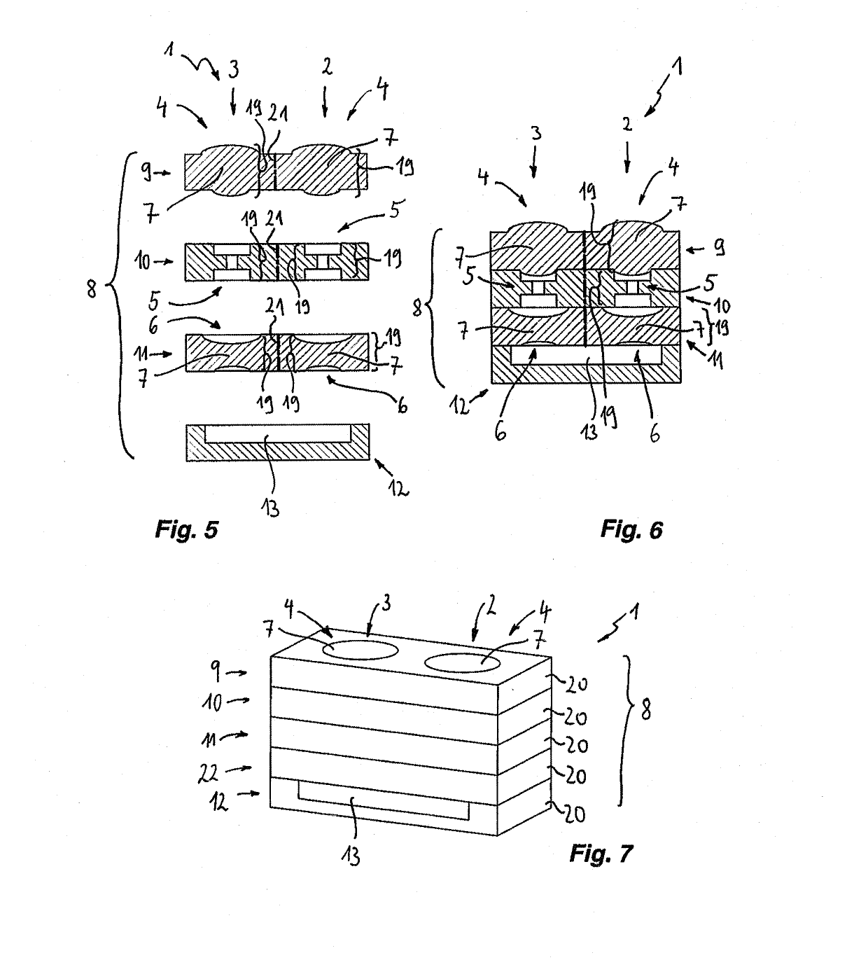

FIGS. 5 and 6 show a further exemplary embodiment according to the invention of an optical arrangement 1, which is again embodied as a stereoscopic optical arrangement.

Component parts and functional units which, structurally and/or functionally, are of the same type as or identical to the exemplary embodiment in accordance with FIGS. 1 to 4 are designated by the same reference signs and will not be described separately again. The explanations concerning FIGS. 1 to 4 are therefore correspondingly applicable to FIGS. 5 and 6.

In the case, too, of the exemplary embodiment in accordance with FIG. 5 and FIG. 6, functional units 9, 10, 11, 12 are formed from a respective wafer 14, 15, 16, 17 in accordance with FIG. 1 and FIG. 2.

In contrast to the exemplary embodiment in accordance with FIG. 3 and FIG. 4, the functional units are formed from a frame 20 that is integrally connected to the respective optical element 4, 5, 6.

Therefore, in the case of the exemplary embodiment in accordance with FIG. 5 and FIG. 6, the functional units 9, 11 have optical elements 4, 6 with lenses 7 which are shaped directly by a shaping of the wafer material of the wafers 14 and 16, respectively.

Therefore, in this exemplary embodiment, the wafers 14, 15, 16, 17 are composed of a transparent material.

In order to reduce crosstalk resulting from stray light transfer, an optically nontransmissive isolation element 21 is therefore formed in each functional unit 9, 10, 11. The isolation elements 21 are aligned with one another, such that an isolation between the optical channels 2, 3 is established overall.

This isolation element 21 can be for example in each case an absorption layer or an absorption part inserted in a molding method.

It should also be mentioned that the wafers 14, 15, 16, 17 in the situation placed one on top of another in accordance with FIG. 2 are cohesively connected, for example adhesively bonded, to one another in the exemplary embodiments described. In particular, a cohesive connection of the frames 20 to one another thus results.

FIG. 7 shows a further optical arrangement 1 according to the invention. Component parts and functional units which, structurally and/or functionally, are of the same type as or identical to the previous exemplary embodiments are designated by the same reference signs and will not be described separately again. The explanations concerning FIGS. 1 to 6 are therefore correspondingly applicable to FIG. 7.

The exemplary embodiment in accordance with FIG. 7 differs from the previous exemplary embodiments in that a further functional unit 22 is formed upstream of the functional unit 12 in which the image sensor chip 13 is arranged.

By way of example, different filters for different wavelengths can be arranged in said further functional unit 22. What can be achieved in this way is that the first optical channel 2 and the second optical channel 3 are designed for different wavelength ranges.

By way of example, the first optical channel 2 can be designed for ultraviolet (UV) wavelength ranges and the second optical channel for infrared (IR) wavelength ranges by virtue of the lenses 7 and/or the filters already mentioned being embodied accordingly.

Alternatively or additionally, the first optical channel can be designed for visible (VIS) wavelength ranges and the second optical channel 3 for UV and/or IR wavelength ranges.

In this case, the image sensor chip 13 can be correspondingly embodied with different sensitivities for the different optical channels 2, 3.

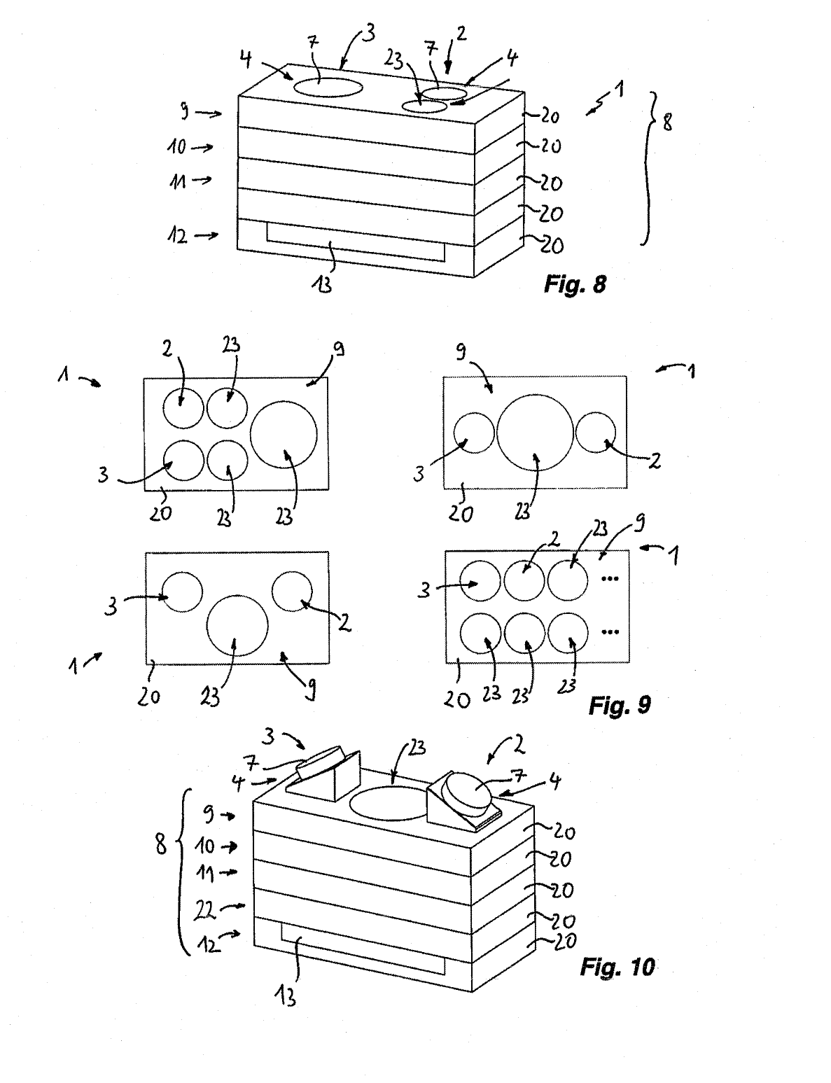

FIG. 8 shows a further exemplary embodiment according to the invention for an optical arrangement 1. Component parts and functional units which, functionally and/or structurally, are of the same type as or identical to the previous exemplary embodiments are designated once again by the same reference signs and will not be described separately again. The explanations concerning the previous exemplary embodiments are therefore correspondingly applicable to FIG. 8.

The exemplary embodiment in accordance with FIG. 8 differs from the previous exemplary embodiments in that a further optical channel 23 is embodied alongside the first optical channel 2 and the second optical channel 3.

In this case, the optical channels 2, 23 can define a first aperture angle, while the second optical channel 3 defines a second, in the example larger, aperture angle.

Alternatively or additionally, the second optical channel 3 can have a larger diaphragm aperture than the optical channels 2, 22.

In this exemplary embodiment, too, the optical channels 2, 3, 23 can be designed for different wavelengths and/or for different focal lengths.

FIG. 9 shows further exemplary embodiments of an optical arrangement 1 according to the invention. The illustration shows in each case views from the front of the functional unit 9 respectively arranged at the distal end.

It is evident that different arrangements of the optical channels 2, 3, 23 are advantageously possible in the case of the invention. These different optical channels 2, 3, 23 can be provided for example for different wavelengths, for different aperture angles, for different diaphragm apertures and/or for different focal lengths.

Further exemplary embodiments for the arrangement of a multiplicity of optical channels having different optical properties can advantageously be used to obtain different items of image information simultaneously. Therefore, the examples illustrated are not exhaustively enumerated, rather further exemplary embodiments are obvious to the person skilled in the art from the examples shown.

In the case of the exemplary embodiments shown, the first optical channel 2 and the second optical channel 3 can be provided and evaluated as right optical channel 2 and as left optical channel 3 of a stereoscopic arrangement 1, but this is not absolutely necessary.

FIG. 10 shows a further optical arrangement according to the invention in a three-dimensional oblique view. Once again component parts and functional units which, functionally and/or structurally, are of the same type as or identical to the previous exemplary embodiments are designated by the same reference signs and will not be described separately again. The explanations concerning the previous exemplary embodiments are therefore correspondingly applicable to FIG. 10.

The exemplary embodiment in accordance with FIG. 10 differs from the previous exemplary embodiments in that the optical channels 2, 3 define different recording directions. Together with the further optical channel 23, a larger total aperture angle can thus be captured.

If the individual aperture angles of the optical channels 2, 3, 23 at least partly overlap, stereoscopic vision can also be established.

In the case of an optical arrangement 1 comprising functional units 9, 10, 11, 12 which are arranged in a stack arrangement 8 and define a first optical channel 2 and a second optical channel 3, it is proposed to form a common image sensor chip for both optical channels 2, 3 in a functional unit 12 and/or to separate the optical channels 2, 3 from one another by means of the functional units 9, 10, 11 without any gaps.

### LIST OF REFERENCE SIGNS

1 Optical arrangement

2 First optical channel

3 Second optical channel

4 Optical element

5 Optical element

6 Optical element

7 Lens

8 Stack arrangement

9 Functional unit

10 Functional unit

11 Functional unit

12 Functional unit

13 Image sensor chip

14 Wafer

15 Wafer

16 Wafer

17 Wafer

18 Cut

19 Section

20 Frame

21 Isolation element

22 Further functional unit

23 Further optical channel

1. An optical arrangement (1), comprising a first optical channel (2) and a second optical channel (3) and optical elements (4, 5, 6) arranged in a stack arrangement (8) in the first optical channel (2) and in the second optical channel (3), respectively corresponding ones of the optical elements (4, 5, 6) of the first optical channel (2) and of the second optical channel (3) are connected to one another as a functional unit (9, 10, 11), and a common image sensor chip (13) detects the first optical channel (2) and the second optical channel (3).

2. An optical arrangement (1), comprising a first optical channel (2) and a second optical channel (3) and optical elements (4, 5, 6) arranged in a stack arrangement (8) in the first optical channel (2) and in the second optical channel (3), respectively corresponding ones of the optical elements (4, 5, 6) of the first optical channel (2) and of the second optical channel (3) are connected to one another as a functional unit (9, 10, 11), and the functional units (9, 10, 11) in the stack arrangement (8) separate the first optical channel (2) from the second optical channel (3) without any gaps.

3. The optical arrangement (1) as claimed in claim 1, wherein the functional units (9, 10, 11, 12) are formed in a plate-shaped fashion.

4. The optical arrangement (1) as claimed in claim 1, wherein the functional units (9, 10, 11, 12) are cut from a wafer (14, 15, 16, 17).

5. The optical arrangement (1) as claimed in claim 1, wherein respectively adjacent ones of the functional units (9, 10, 11, 12) are placed onto one another directly.

6. The optical arrangement (1) as claimed in claim 1, wherein respectively adjacent ones of the functional units (9, 10, 11, 12) are placed onto one another without any gaps

7. The optical arrangement as claimed in claim 1, wherein the first optical channel (2) and the second optical channel (3) are formed in each case by mutually aligned sections (19) in the functional units (9, 10, 11), said sections accommodate or form a respective optical element (4, 5, 6).

8. The optical arrangement as claimed in claim 7, wherein for each of the functional units (9, 10, 11), the section (19) of the first optical channel (2) is arranged at a distance from the section (19) of the second optical channel (3).

9. The optical arrangement (1) as claimed in claim 1, wherein the functional units (9, 10, 11, 12) in each case have a frame (20) comprised of a wafer (14, 15, 16, 17), or an optically nontransmissive material, or a wafer comprised of an optically nontransmissive material.

10. The optical arrangement (1) as claimed in claim 1, wherein at least one of the functional units (9, 10, 11) has an optical isolation element (21) between the first optical channel (2) and the second optical channel (3).

11. The optical arrangement (1) as claimed in claim 1, wherein at least one of the first optical channel (2) or the second optical channel (3) is closed off transversely with respect to a course direction on all sides toward at least one of an outside or relative to one another.

12. The optical arrangement (1) as claimed in claim 1, wherein the functional units (9, 10, 11, 12) are at least one of injection molded, pressed, stamped or embossed.

13. The optical arrangement (1) as claimed in claim 1, wherein the optical arrangement (1) is a stereoscopic optical arrangement (1).

14. The optical arrangement (1) as claimed in claim 13, wherein the first optical channel (2) is a right optical channel, the second optical channel (3) is a left optical channel, or both.

15. The optical arrangement (1) as claimed in claim 13, wherein the first optical channel (2) and the second optical channel (3) are designed for mutually differing wavelength ranges, define different aperture angles, recording directions, diaphragm apertures, or focal lengths from one another.

16. An endoscope comprising an optical arrangement (1) as claimed in claim 1.

17. A method for producing an optical arrangement (1) in which the optical arrangement (1) has a stack arrangement (8) of functional units (9, 10, 11, 12) respectively defining a first optical channel (2) and a second optical channel (3), comprising forming the functional units (9, 10, 11, 12) on a respective wafer (14, 15, 16, 17), placing the wafers (14, 15, 16, 17) with the functional units (9, 10, 11, 12) onto one another in order to form the stack arrangement (8), and cutting apart the wafers (14, 15, 16, 17) that are placed onto one another in order to singulate the optical arrangement (1).

18. The method as claimed in claim 17, wherein the respective functional unit (9, 10, 11, 12) is formed multiply on each of the wafers (14, 15, 16, 17).

19. The method as claimed in claim 17, further comprising cohesively connecting the wafers (14, 15, 16, 17) in the position placed onto one another to one another.

20. The method as claimed in claim 17, further comprising producing the functional units (9, 10, 11, 12) by at least one of injection molding, pressing, stamping, or embossing method.
